(19) United States
(12) Patent Application Publication
(10) Pub. No.: US 2008/0156365 A1
(43) Pub. Date: Jul. 3, 2008

(54) EDGE MOUNTABLE ELECTRICAL CONNECTION ASSEMBLY

(76) Inventors: Jeremy H. Scholz, Sunnyvale, CA (US); Paul M. Adriani, Palo Alto, CA (US)

Correspondence Address: Director of IP, 5521 Hellyer Avenue, San Jose, CA, 95138, US

(21) Appl. No.: 11/924,594

(22) Filed: Oct. 25, 2007

Related U.S. Application Data
(60) Provisional application No. 60/862,979, filed on Oct. 25, 2006.

(51) Int. Cl. H01L 31/048

(52) U.S. Cl. 136/251; 136/244

(57) ABSTRACT

Methods and devices are provided for improved large-scale solar installations. In one embodiment, a photovoltaic module is provided comprising of a plurality of photovoltaic cells positioned between a transparent module layer and a backside module layer. The module includes a first electrical lead extending outward from an edge of the module from between the transparent module layer and the backside module layer, wherein the lead is couplable to an adjacent module without passing the lead through a central junction box or an opening in either the transparent module layer or the backside module layer. The module may include a second electrical lead extending outward from an edge of the module from between the transparent module layer and the backside module layer, wherein the lead is couplable to another adjacent module without passing the lead through a central junction box or an opening in either the transparent module layer or the backside module layer.

### CROSS-REFERENCE TO RELATED APPLICATIONS

This application claims the benefit of priority to U.S. Provisional Application Ser. No. 60/862,979 filed Oct. 25, 2006, fully incorporated herein by reference for all purposes.

### FIELD OF THE INVENTION

This invention relates generally to photovoltaic devices, and more specifically, to solar cells and/or solar cell modules designed for large-scale electric power generating installations.

### BACKGROUND OF THE INVENTION

Solar cells and solar cell modules convert sunlight into electricity. Traditional solar cell modules are typically comprised of polycrystalline and/or monocrystalline silicon solar cells mounted on a support with a rigid glass top layer to provide environmental and structural protection to the underlying silicon based cells. This package is then typically mounted in a rigid aluminum or metal frame that supports the glass and provides attachment points for securing the solar module to the installation site. A host of other materials are also included to make the solar module functional. This may include junction housings, bypass diodes, sealants, and/or multi-contact connectors used to complete the module and allow for electrical connection to other solar modules and/or electrical devices. Certainly, the use of traditional silicon solar cells with conventional module packaging is a safe, conservative choice based on well understood technology.

Drawbacks associated with traditional solar module package designs, however, have limited the ability to install large numbers of solar panels in a cost-effective manner. This is particularly true for large scale deployments where it is desirable to have large numbers of solar modules setup in a defined, dedicated area. Traditional solar module packaging comes with a great deal of redundancy and excess equipment cost. For example, a recent installation of conventional solar modules in Pocking, Germany deployed 57,912 monocrystalline and polycrystalline-based solar modules. This meant that there were also 57,912 junction housings, 57,912 aluminum frames, untold meters of cablings, and numerous other components. These traditional module designs inherit a large number of legacy parts that hamper the ability of installers to rapidly and cost-efficiently deploy solar modules at a large scale.

Although subsidies and incentives have created some large solar-based electric power installations, the potential for greater numbers of these large solar-based electric power installations has not been fully realized. There remains substantial improvement that can be made to photovoltaic cells and photovoltaic modules that can greatly reduce their cost of manufacturing, increase their ease of installation, and create much greater market penetration and commercial adoption of such products, particularly for large scale installations.

### SUMMARY OF THE INVENTION

Embodiments of the present invention address at least some of the drawbacks set forth above. The present invention provides for the improved solar module designs that reduce manufacturing costs and redundant parts in each module. These improved module designs are well suited for installation at dedicated sites where redundant elements can be eliminated since some common elements or features may be shared by many modules. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

In one embodiment of the present invention, a central junction-boxless photovoltaic module is used comprising of a plurality of photovoltaic cells and a module support layer providing a mounting surface for the cells. The module has a first electrical lead extending outward from one of the photovoltaic cells, the lead coupled to an adjacent module without passing the lead through a central junction box. The module may have a second electrical lead extending outward from one of the photovoltaic cells, the lead coupled to another adjacent module without passing the lead through a central junction box. Without central junction boxes, the module may use connectors along the edges of the modules which can substantially reduce the amount of wire or connector ribbon used for such connections.

In another embodiment of the present invention, a photovoltaic module is provided comprising of a plurality of photovoltaic cells positioned between a transparent module layer and a backside module layer. The module includes a first electrical lead extending outward from an edge of the module from between the transparent module layer and the backside module layer, wherein the lead is couplable to an adjacent module without passing the lead through a central junction box or an opening in either the transparent module layer or the backside module layer. Optionally, some embodiments may use electrical leads that exit though an opening in the module. Optionally, some embodiments may use electrical leads that exit though an opening in the transparent module layer or the backside module layer. The module may include a second electrical lead extending outward from an edge of the module from between the transparent module layer and the backside module layer, wherein the lead is couplable to another adjacent module without passing the lead through a central junction box or an opening in either the transparent module layer or the backside module layer.

Optionally, the following may also be adapted for use with any of the embodiments disclosed herein. The module support layer may be frameless and thus creates a frameless photovoltaic module. The backside module layer, transparent module layer, and the cells therebetween may be coupled together without a frame extending partially around or completely around a perimeter of the module layers. The module may be a glass-glass module. The transparent module layer may be comprised of solar glass. The transparent module layer may have a thickness of about 4.0 mm or less. The transparent module layer may have a thickness of about 3.2 mm or less. The backside module layer may be comprised of non-solar glass. The backside module layer may have a thickness of about 3.0 mm or less. The backside module layer may have a thickness of about 2.0 mm or less. The module may further include a pottant layer between the photovoltaic cells and either the transparent module layer or the backside layer, wherein the pottant layer has thickness of about 100 microns or less. In other embodiments, the pottant layer may have a thickness of about 50 microns or less. The pottant layer between the photovoltaic cells and either the transparent module layer or the backside layer may be comprised of one or more of the following: ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, or combinations thereof. The first electrical lead may be a flat, square, rectangular, triangular, round, or connector with other cross-sectional shape. The second electrical lead may be the same or different shape as the first electrical lead.

Optionally, the following may also be adapted for use with any of the embodiments disclosed herein. The photovoltaic cells may be in direct contact with the transparent module layer. The photovoltaic cells may be in direct contact with the backside module layer. The photovoltaic cells comprise of thin-film photovoltaic cells. The photovoltaic cells may be comprised of non-silicon solar cells. The photovoltaic cells may be comprised of amorphous silicon-base solar cells. Optionally, the photovoltaic cells each have an absorber layer with one or more inorganic materials from the group consisting of: titania (TiO₂), nanocrystalline TiO₂, zinc oxide (ZnO), copper oxide (CuO or Cu₂O or CuₓO_{y}), zirconium oxide, lanthanum oxide, niobium oxide, tin oxide, indium oxide, indium tin oxide (ITO), vanadium oxide, molybdenum oxide, tungsten oxide, strontium oxide, calcium/titanium oxide and other oxides, sodium titanate, potassium niobate, cadmium selenide (CdSe), cadmium sulfide (CdS), copper sulfide (Cu₂S), cadmium telluride (CdTe), cadmium-tellurium selenide (CdTeSe), copper-indium selenide (CuInSe₂), cadmium oxide (CdOₓ), CuI, CuSCN, a semiconductive material, silicon, or combinations of the above. Optionally, the photovoltaic cells may each have an absorber layer with one or more organic materials from the group consisting of: a conjugated polymer, poly(phenylene) and derivatives thereof, poly(phenylene vinylene) and derivatives thereof (e.g., poly(2-methoxy-5-(2-ethyl-hexyloxy)-1,4-phenylene vinylene (MEH-PPV), poly(para-phenylene vinylene), (PPV)), PPV copolymers, poly(thiophene) and derivatives thereof (e.g., poly(3-octylthiophene-2,5-diyl), regioregular, poly(3-octylthiophene-2,5-diyl), regiorandom, Poly(3-hexylthiophene-2,5-diyl), regioregular, poly(3-hexylthiophene-2,5-diyl), regiorandom), poly(thienylenevinylene) and derivatives thereof, and poly(isothianaphthene) and derivatives thereof, 2,2′7,7′tetrakis(N,N-di-p-methoxyphenyl-amine)-9,9′-spirobifluorene(spiro-Me OTAD), organometallic polymers, polymers containing perylene units, poly(squaraines) and their derivatives, and discotic liquid crystals, organic pigments or dyes, a Ruthenium-based dye, a liquid iodide/triiodide electrolyte, azo-dyes having azo chromofores (—N═N—) linking aromatic groups, phthalocyanines including metal-free phthalocyanine; (HPc), perylenes, perylene derivatives, copper phthalocyanines (CuPc), zinc phthalocyanines (ZnPc), naphthalocyanines, squaraines, merocyanines and their respective derivatives, poly(silanes), poly(germinates), 2,9-Di(pent-3-yl)-anthra[2,1,9-def:6,5,10-d′e′f′]diisoquinoline-1,3,8,10-tetrone, and 2,9-Bis-(1-hexyl-hept-1-yl)-anthra[2,1,9-def:6,5,10-d′e′f′]diisoquinoline-1,3,8,10-tetrone and pentacene, pentacene derivatives and/or pentacene precursors, an N-type ladder polymer, poly(benzimidazobenzophenanthroline ladder) (BBL), or combinations of the above. The photovoltaic cells may each have an absorber layer with one or more materials from the group consisting of: an oligomeric material, micro-crystalline silicon, inorganic nanorods dispersed in an organic matrix, inorganic tetrapods dispersed in an organic matrix, quantum dot materials, ionic conducting polymer gels, sol-gel nanocomposites containing an ionic liquid, ionic conductors, low molecular weight organic hole conductors, C60 and/or other small molecules, or combinations of the above.

Optionally, the following may also be adapted for use with any of the embodiments disclosed herein. The first electrical lead or the second electrical lead may be comprised of a flat wire or ribbon. The first electrical lead or the second electrical lead may be comprised of a flat aluminum wire. The first electrical lead or the second electrical lead may be comprised of a length no more than about 2× a distance from one edge of the module to an edge of a closest adjacent module. Optionally, the first electrical lead or the second electrical lead may have a length no more than about 30 cm. The module may be in landscape configuration defined by a long dimension and a short dimension, wherein the first electrical lead extends from the module along the short dimension. The module may be in landscape configuration defined by a long dimension and a short dimension, wherein the first electrical lead extends from the module along the long dimension, closer to one end of the module than a middle of the module. The first electrical lead may extend outward from one edge of the module and the second electrical lead may extend outward from the same edge of the module. In another embodiment, the first electrical lead extends outward from along one edge of the module and the second electrical lead extends outward from a different edge of the module.

Optionally, the following may also be adapted for use with any of the embodiments disclosed herein. The module may include a first edge housing for securing the first electrical lead to the module and providing a moisture barrier at a first electrical lead exit from the module. The module may also include a second edge housing for securing the second electrical lead to the module and providing a moisture barrier at a second electrical lead exit from the module. The first edge housing and the second edge housing may each define an interior space configured to accommodate encapsulant material injected into the space to form the moisture barrier. The first edge housing and the second edge housing may each have an opening allowing encapsulant material to be injected into the connecter to form a moisture barrier after the connecter is mounted onto the module. The first edge housing and the second edge housing may each have a surface that engages the transparent module layer and a second surface that engages the backside module layer. The first edge housing and the second edge housing may engage only one of the following: the transparent module layer or the backside module layer. The first edge housing and the second edge housing may each sized to receive a flat wire entering the edge housing and couple the flat wire to a round wiring exiting the edge housing. The first edge housing and the second edge housing may each be sized to receive a flat aluminum-based wire entering the edge housing and couple the flat aluminum-based wire to a round copper-based wire exiting the edge housing. The first edge housing and the second edge housing may be spaced apart from one another, with the first edge housing closer to one end of the module and the second edge housing to an opposite end of the module. The first edge housing and the second edge housing may each be positioned on the module to cover a corner of the module. The first edge housing and the second edge housing may extend no more than about 1 cm above the transparent module layer. The first edge housing and the second edge housing may extend no more than about 0.5 cm above the transparent module layer. The first edge housing and the second edge housing may extend no more than about 0.5 cm below the backside module layer. In another embodiment, the height may be no more than about 0.25 cm above the module layer. In another embodiment, the height may be no more than about 0.10 cm above the module layer. The first edge housing and the second edge housing may be mounted in a manner along the edges of the module to allow for substantially flush stacking of modules against one another. It should be understood that the term edge does not necessarily mean that the edge housing is coupled to the edge or side edge of the module. Although some embodiments of the edge housings do have this configuration, others are merely away for the centerline of the module and typically closer to an adjacent module than a centerline and/or center point of the module.

Optionally, the following may also be adapted for use with any of the embodiments disclosed herein. A first cell in the module may be comprised of a dummy cell of non-photovoltaic material to facilitate electrical connection to other solar cells in the module. A flat, inline bypass diode takes the place of one of the cells in the module. The module may be without a bypass diode. The module may include a moisture barrier extending along the perimeter of the module to prevent moisture entry into the module. Although not limited to the following, the moisture barrier may be a butyl rubber based material such as that available from TruSeal Technologies, Inc. A desiccant loaded edge seal may be used to act as a moisture barrier around the module. The moisture barrier may be one or more of the following: butyl tape or butyl tape loaded with desiccant. An edge seal may be provided as a moisture barrier. A desiccant loaded edge seal may be provided a moisture barrier. The module may have a weight of about 16 kg or less. The module may have a weight of about 16 kg or less without including any mounting bracket. The module may have a cross-sectional thickness of about 6 mm or less, including at least the thickness of the cells, the transparent module layer, and the backside module layer. The module may have a cross-sectional thickness of about 7 mm or less, including at least the thickness of the cells, the transparent module layer, and the backside module layer. The module may have a length between about 1660 mm and about 1666 mm. The module may have a width between about 700 mm and about 706 mm. The module may be designed to be coupled to a plurality of clips to couple the module to support structures. The module may be designed to be coupled to four clips attached to edges of the module to couple the module to support rails. Although modules may be shown oriented in portrait orientation, it should be understood they may also be in landscape orientation. The electrical connector may exit from edges closest to next module or device that the current module is connected to. Optionally, the electrical connector may exit from the orthogonal edge. The electrical connectors may exit from the same edge, from opposing edges, or form other different edges. The thickness of the modules layers may optionally be the same or different.

In yet another embodiment of the present invention, an edge housing provided use with a solar module may be comprised of a housing defining an opening for receiving an electrical lead from the module and a module interface surface on the housing configured to mount the housing along an edge of the module. The housing may define a cavity for receiving encapsulant to create a waterproof seal with the module and the electrical lead.

Optionally, the following may also be adapted for use with any of the embodiments disclosed herein. The housing may be comprised of an upper part and a lower part separable from one another. The housing may have a clam-shell design wherein an upper part of the housing is hinged to a lower part of the housing. The housing may define an interior space along one or more surfaces facing the module and configured to accommodate encapsulant material injected into the space to form a moisture barrier against the module. The housing may include an opening to allow encapsulant material to be injected into the housing after the housing is mounted to the solar module. The housing may have a surface that engages the transparent module layer and a second surface that engages the backside module layer. The housing optionally engages only one of the following: the transparent module layer or the backside module layer. The housing may be sized to receive a flat wire entering the edge housing and couple the flat wire to a round wiring exiting the housing. The housing may be sized to compress a flat wire entering the housing against a round wiring exiting the housing. The first edge housing and the second edge housing may each be sized to receive a flat aluminum-based wire entering the edge housing and couple the flat aluminum-based wire to a round copper-based wire exiting the edge housing. The housing may be comprised of injection molded plastic. The housing may include locators and/or locator marks to align parts of the housing together. The housing may be shaped to cover a corner of the module to increase surface area contact between the housing and the module. The module may be without a central junction box that comprises a junction housing that contains both an electrical lead from an upstream solar module and an electrical lead to a downstream solar module.

In yet another embodiment of the present invention, a photovoltaic power installation is provided comprised of a plurality of frameless photovoltaic modules. A plurality of electrical leads from each of the modules, wherein adjacent modules are coupled together by at least one of the electrical leads extending outward from the modules, each of the leads extending outward without passing through a central junction box. In some embodiment, each of the photovoltaic modules includes at least two edge housings for electrical leads extending outward from each module.

Optionally, the following may also be adapted for use with any of the embodiments disclosed herein. The edge housings may be filled with encapsulant after being mounted on the modules. The edge housings may be electrically coupled a flat wire from the modules to a round wire extending from the edge housings. The edge housings may optionally extend no more than about 0.5 cm above or below a top or bottom surface of the modules to minimize stacking height. The edge housings may optionally extend no more than about 0.25 cm above or below a top or bottom surface of the modules to minimize stacking height. The edge housings may optionally extend no more than about 0.1 cm above or below a top or bottom surface of the modules to minimize stacking height. The edge housings on one module may be spaced apart from one another. The electrical leads may each have a length less than about 2× a distance separating adjacent modules. The modules may be coupled in a series interconnection. The modules may be glass-glass modules with a glass-based top layer and a glass-based bottom layer. The modules may be frameless and mounted on a plurality of rails. The modules may be frameless and mounted on a plurality of rails, wherein the rails carry electrical charge between modules.

In a still further embodiment of the invention, a method is provided comprising of providing a plurality of frameless, rigid photovoltaic modules and mounting a plurality of edge housings over electrical leads extending outward from the edges of the modules, wherein all electrical leads on one module exits the module without passing through the same edge housing and without passing through a central junction box.

Optionally, the following may also be adapted for use with any of the embodiments disclosed herein. Mounting the edge housings comprises adhering the edge connecters to at least one planar surface on the modules. The method may include mounting the edge housings comprises adhering the edge connecters to both top and bottom surfaces of the modules. Edge housings may be positioned on the modules without substantially covering any solar cells in the module. The modules may be glass-glass modules. The edge housings may be filled with encapsulant before mounting on the modules. The edge housings may be filled with encapsulant after mounting on the modules. Electrical leads may extend outward from the module between module layers and without passing through openings in the module layers. Mechanical pressure may be used to electrically connect two bare electrical conductors within the housing. Each of the electrical connectors provides a sealing surface of at least about 2 cm² areas. Optionally, each of the electrical connectors provides a sealing surface of at least about 1 cm² area. The photovoltaic modules may be electrically coupled together at the installation site in a series interconnected manner, wherein the electrically coupling step comprises at least one of the following methods for joining electrical leads: welding, spot welding, reflow soldering, ultrasonic welding, arc welding, cold welding, laser welding, induction welding, or combinations thereof. Adjacent electrical leads may be joined together to form a V-shape or Y-shape connection. Optionally, adjacent electrical leads may be joined together to form a U-shape connection.

In one embodiment of the present invention, a central junction-boxless photovoltaic module is used comprising of a plurality of photovoltaic cells, a transparent module layer, and a backside module layer. The module may have a first edge-exiting electrical lead extends outward from the module from between the transparent module layer and the backside module layer, wherein the first edge-exiting electrical lead is couplable to an adjacent module without passing the lead through a central junction box; and a second edge-exiting electrical lead extending outward from the module from between the transparent module layer and the backside module layer, wherein the second edge-exiting electrical lead is couplable to another adjacent module without passing the lead through a central junction box. Optionally, the edge exiting leads are each housed within an edge mounted edge housing that contains only one connection directly connected to at least one cell in the module. Optionally, the edge exiting leads are each housed within an edge mounted edge housing that contains only one connection directly connected to only one cell in the module. Optionally, the edge exiting leads are each housed within an edge mounted edge housing that connects to a wire exiting through an opening in the backside module layer.

A further understanding of the nature and advantages of the invention will become apparent by reference to the remaining portions of the specification and drawings.

### BRIEF DESCRIPTION OF THE DRAWINGS

FIG. 1 is an exploded perspective view of a module according to one embodiment of the present invention.

FIG. 2 shows a cross-sectional view of a module according to one embodiment of the present invention.

FIG. 3 shows a cross-sectional view of a module according to one embodiment of the present invention.

FIG. 4 shows a cross-sectional view of a module according to yet another embodiment of the present invention.

FIG. 5 shows a cross-sectional view of a module according to yet another embodiment of the present invention.

FIG. 6 is a cross-sectional view showing a module with a moisture barrier according to one embodiment of the present invention.

FIGS. 7A-7B are cross-sectional views showing a module with a moisture barrier according to various embodiments of the present invention.

FIGS. 8, 9A, and 9B are top down views of modules with cells according to various embodiments of the present invention.

FIGS. 10, 11A, and 11B are top down views of modules with elongated cells according to various embodiments of the present invention.

FIGS. 12-14B show various views of an edge housing according to one embodiment of the present invention.

FIGS. 15-16 show a top view and a side view of an edge housing according to yet another embodiment of the present invention.

FIGS. 17-18 show a top view and a side view of an edge housing according to yet another embodiment of the present invention.

FIG. 19 shows a cross-sectional view of an edge housing according to yet another embodiment of the present invention.

FIGS. 20 and 21 are top down views of edge housings according to various embodiments of the present invention.

FIGS. 22A-22D show various views of an edge housing according to embodiments of the present invention.

FIGS. 23-25 show various views of an edge housing according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

### Photovoltaic Module

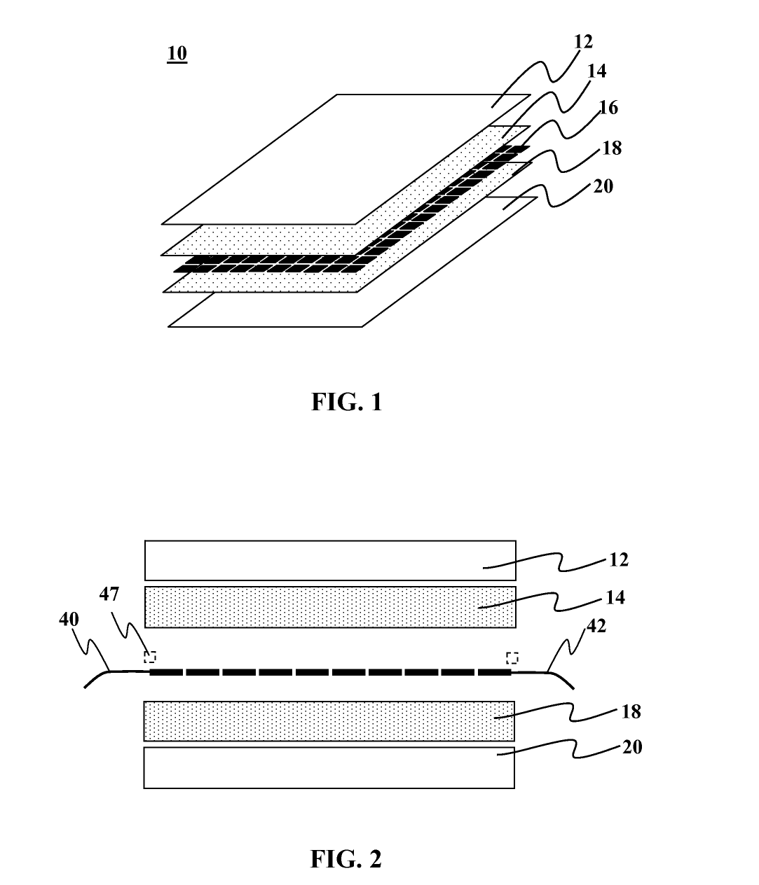

Referring now to FIG. 1, one embodiment of a module 10 according to the present invention will now be described. As module 10 is designed for large scale installation at sites dedicated for solar power generation, many features have been optimized to reduce cost and eliminate redundant parts. Traditional module packaging and system components were developed in the context of legacy cell technology and cost economics, which had previously led to very different panel and system design assumptions than those suited for increased product adoption and market penetration. The cost structure of solar modules includes both factors that scale with area and factors that are fixed per module. Module 10 is designed to minimize fixed cost per module and decrease the incremental cost of having more modules while maintaining substantially equivalent qualities in power conversion and module durability. In this present embodiment, the module 10 may include improvements to the backsheet, frame modifications, thickness modifications, and electrical connection modifications.

FIG. 1 shows that the present embodiment of module 10 may include a rigid transparent upper layer 12 followed by a pottant layer 14 and a plurality of solar cells 16. Below the layer of solar cells 16, there may be another pottant layer 18 of similar material to that found in pottant layer 14. Beneath the pottant layer 18 may be a layer of backsheet material 20. The transparent upper layer 12 provides structural support and acts as a protective barrier. By way of nonlimiting example, the transparent upper layer 12 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. The total thickness of the glass or multi-layer glass may be in the range of about 2.0 mm to about 13.0 mm, optionally from about 2.8 mm to about 12.0 mm. In one embodiment, the top layer 12 has a thickness of about 3.2 mm. In another embodiment, the backlayer 20 has a thickness of about 2.0 mm. As a nonlimiting example, the pottant layer 14 may be any of a variety of pottant materials such as but not limited to Tefzel®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof. Optionally, some embodiments may have more than two pottant layers. The thickness of a pottant layer may be in the range of about 10 microns to about 1000 microns, optionally between about 25 microns to about 500 microns, and optionally between about 50 to about 250 microns. Others may have only one pottant layer (either layer 14 or layer 16). In one embodiment, the pottant layer 14 is about 75 microns in cross-sectional thickness. In another embodiment, the pottant layer 14 is about 50 microns in cross-sectional thickness. In yet another embodiment, the pottant layer 14 is about 25 microns in cross-sectional thickness. In a still further embodiment, the pottant layer 14 is about 10 microns in cross-sectional thickness. The pottant layer 14 may be solution coated over the cells or optionally applied as a sheet that is laid over cells under the transparent module layer 12.

It should be understood that the simplified module 10 is not limited to any particular type of solar cell. The solar cells 16 may be silicon-based or non-silicon based solar cells. By way of nonlimiting example the solar cells 16 may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. Advantageously, thin-film solar cells have a substantially reduced thickness as compared to silicon-based cells. The decreased thickness and concurrent reduction in weight allows thin-film cells to form modules that are significantly thinner than silicon-based cells without substantial reduction in structural integrity (for modules of similar design).

The pottant layer 18 may be any of a variety of pottant materials such as but not limited to EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof as previously described for FIG. 1. The pottant layer 18 may be the same or different from the pottant layer 14. Further details about the pottant and other protective layers can be found in commonly assigned, co-pending U.S. patent application Ser. No. 11/462,359 (Attorney Docket No. NSL-090) filed Aug. 3, 2006 and fully incorporated herein by reference for all purposes. Further details on a heat sink coupled to the module can be found in commonly assigned, co-pending U.S. patent application Ser. No. 11/465,783 (Attorney Docket No. NSL-089) filed Aug. 18, 2006 and fully incorporated herein by reference for all purposes.

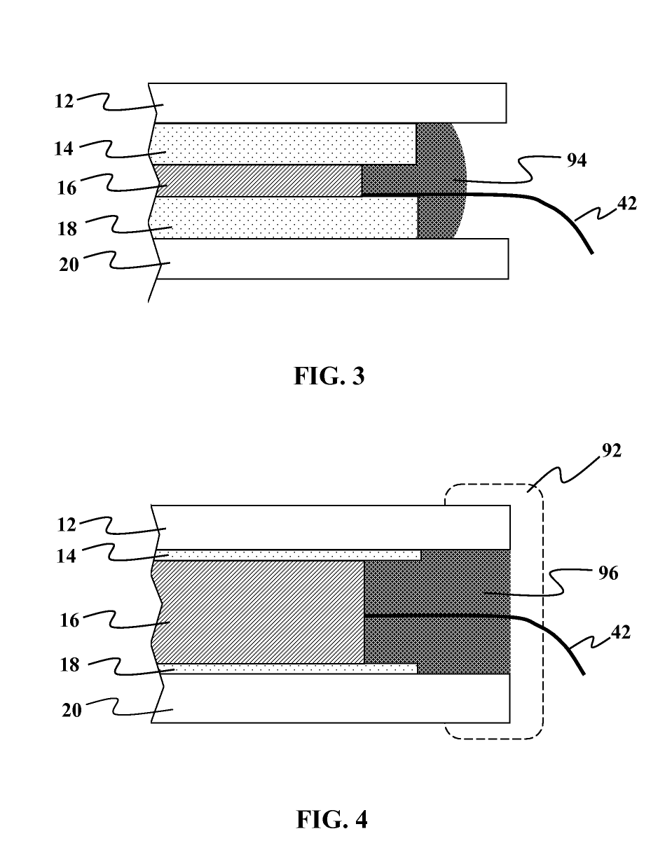

FIG. 2 shows a cross-sectional view of the module of FIG. 1. By way of nonlimiting example, the thicknesses of backsheet 20 may be in the range of about 10 microns to about 1000 microns, optionally about 20 microns to about 500 microns, or optionally about 25 to about 250 microns. Again, as seen for FIG. 2, this embodiment of module 10 is a frameless module without a central junction box. The present embodiment may use a simplified backsheet 20 that provides protective qualities to the underside of the module 10. As seen in FIG. 1, the module may use a rigid backsheet 20 comprised of a material such as but not limited to annealed glass, heat strengthened glass, tempered glass, flow glass, cast glass, or similar materials as previously mentioned. The rigid backsheet 20 may be made of the same or different glass used to form the upper transparent module layer 12. Optionally, in such a configuration, the top sheet 12 may be a flexible top sheet such as that set forth in U.S. Patent Application Ser. No. 60/806,096 (Attorney Docket No. NSL-085P) filed Jun. 28, 2006 and fully incorporated herein by reference for all purposes.

### Electrical Edge Connection

As seen in FIGS. 1 and 2, embodiments of the present invention minimize per-module costs and minimizes per-area costs by eliminating legacy components whose functions can be more elegantly addressed by improved mounting and wiring designs. By way of nonlimiting example as seen in FIGS. 1 and 2, one method of reducing cost and complexity is to provide edge exiting electrical connections, without the use of a central junction box. FIG. 1 shows that module 10 is designed to allow a wire or wire ribbon to extend outward from the module 10 or a solder connection to extend inward to a ribbon below. This outward extending wire or ribbon 40 or 42 may then be connected to another module, a solar cell in another module, and/or an electrical lead from another solar module to create an electrical interconnection between modules. Elimination of the junction housing removes the requirement that all wires extend outward from one location on the module. Having multiple exit points allows those exits points to be moved closer to the objects they are connected to and this in turn results in significant savings in wire or ribbon length.

FIG. 2 shows a cross-sectional view of the central junction box-less module 10 where the ribbons 40 and 42 are more easily visualized. The ribbon 40 may connect to a first cell in a series of electrically coupled cells and the ribbon 42 may connect to the last cell in the series of electrically coupled cells. Optionally, the wires or ribbons 40 and 42 may themselves have a coating or layer to electrically insulate themselves from the backsheet 20. FIG. 2 also shows that one of the pottant layers 14 or 18 may be optionally removed. The electrical lead wires/ribbons 40 and 42 may extend outward from between the top sheet 12 and the backsheet 20. By way of nonlimiting example, the pottant layer may be EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof. There may be a moisture barrier 47 (shown in phantom) optionally included in the module. By way of nonlimiting example, the barrier 47 may be a butyl rubber, non-butyl rubber polymer, or other material used for moisture barriers as is known in the art.

As seen in FIG. 3, the electrical leads can also be designed to exit along the sides of the module, between the various layers 12 and 20, rather than through them. This simplifies the issue of having to form openings in hardened, brittle substrates such as glass which may be prone to breakage if the openings are improperly formed during such procedures. It should be understood, of course, some embodiments may use an edge housing or edge housings with electrical leads that exit through one or more openings in the module or one of the module layers. The solar cell 16 in FIG. 3 may be recessed so that moisture barrier material 94 may be applied along a substantial length of the edge of the module. This creates a longer seal area before moisture can reach the solar cell 16. The barrier material 94 may also act as a strain relief for the ribbon 42 extending outward from the module. By way of nonlimiting example, some suitable material for barrier material 94 include a high temperature thixotropic epoxy such as EPO-TEK® 353ND-T from Epoxy Technology, Inc., a ultraviolet curable epoxy such as EPO-TEK® OG116-31, or a one component, non-conductive epoxy adhesive such as ECCOSEAL™ 7100 or ECCOSEAL™ 7200 from Emersion & Cuming. In one embodiment, the materials may have a water vapor permeation rate (WVPR) of no worse than about 5×10⁻⁴ g/m² day cm at 50° C. and 100% RH. In other embodiments, it may be about 4×10⁻⁴ g/m² day cm at 50° C. and 100% RH. In still other embodiments, it may be about 3×10⁻⁴ g/m² day cm at 50° C. and 100% RH. FIG. 3 also shows that the electrical lead 42 may extend from one side of the cell 16 (either top or bottom) and not necessarily from the middle.

Referring now to FIG. 4, it is shown that in other embodiments, barrier material 96 may extend from the solar cell 16 to the edge of the module and create an even longer moisture barrier area. The electrical lead 42 extends outward from the side of the module and the barrier material 96 may still act as an area of strain relief. FIG. 4 shows that in some embodiments, the solar cell 16 has a substantially larger cross-sectional thickness than the pottant layers 14 and/or 18. Some embodiments may have only one pottant layer. Other embodiments may have no pottant layers.

For any of the embodiments herein, a perimeter seal 92 (shown in phantom) may optionally be applied around the module 10 to improve the barrier seal along the side perimeter of the module. This perimeter seal 92 will reinforce the barrier properties along the sides of the module 10 and prevent sideway entry of fluid into the module. The seal 92 may be comprised of one or more of the following materials such as but not limited to desiccant loaded versions of EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof. By way of nonlimiting example, the desiccant may be selected from porous internal surface area particle of aluminosilicates, aluminophosphosilicates, or similar material. It should be understood that the seal 92 may be applied to any of the modules described herein to reinforce their barrier properties. In some embodiments, the seal 92 may also act as strain relief for ribbons, wires, or other elements exiting the module. Optionally, the seal 92 may also be used to house certain components such as bypass diodes or the like which may be embedded in the seal material.

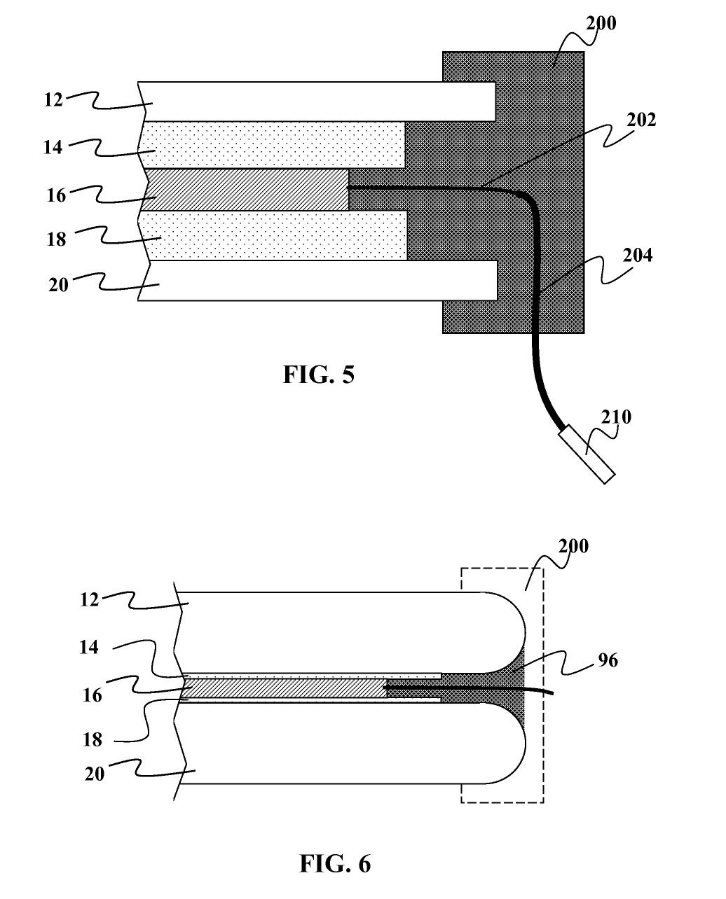

FIG. 5 shows a vertical cross-section of the module that may include a rigid transparent upper layer 12 followed by a pottant layer 14 and a plurality of solar cells 16. Below the layer of solar cells 16, there may be another pottant layer 18 of similar material to that found in pottant layer 14. A rigid backsheet 62 such as but not limited to a glass layer may also be included. FIG. 5 shows that an improved moisture barrier and strain relief element 200 may be included at the location where the electrical connector lead away from the module. As seen in FIG. 5, in some embodiments, a transition from a flat wire 202 to a round wire 204 may also occur in the element 200. Optionally, instead of and/or in conjunction with the shape change, transition of material may also occur. By way of nonlimiting example, the transition may be aluminum-to-copper, copper-to-aluminum, aluminum-to-aluminum (high flex), or other metal to metal transitions. Of course, the wire 204 outside of the moisture barrier and strain relief element 200 is preferably electrically insulated.

FIG. 5 also shows that a solder sleeve 210 may also be used with the present invention to join two electrical connectors together. The solder sleeve 210 may be available from companies such as Tyco Electronics. The solder sleeve may include solder and flux at the center of the tube, with hot melt adhesive collars at the ends of the tube. When heated to sufficient temperature by a heat gun, the heat shrink nature of the solder sleeve 210 will compress the connectors while also soldering the connectors together. The hot melt adhesive and the heat shrink nature of the material will then hold the connectors together after cooling. This may simplify on-site connection of electrical connectors and provide the desired weatherproofing/moisture barrier.

FIG. 6 shows that for some embodiments of the present invention, the upper layer 12 and back sheet 62 are significantly thicker than the solar cells 16 and pottant layers 14 or 18. The layers 12 and 62 may be in the range of about 2.0 to about 4.0 mm thick. In other embodiments, the layers may be in the range of about 2.5 to about 3.5 mm thick. The layer 12 may be a layer of solar glass while the layer 62 may be layer of non-solar glass such as tempered glass. In some embodiments, the layer 12 may be thicker than the layer 62 or vice versa. The edges of the layers 12 and 62 may also be rounded so that the any moisture barrier material 96. The curved nature of the edges provides more surface area for the material 96 to bond against.

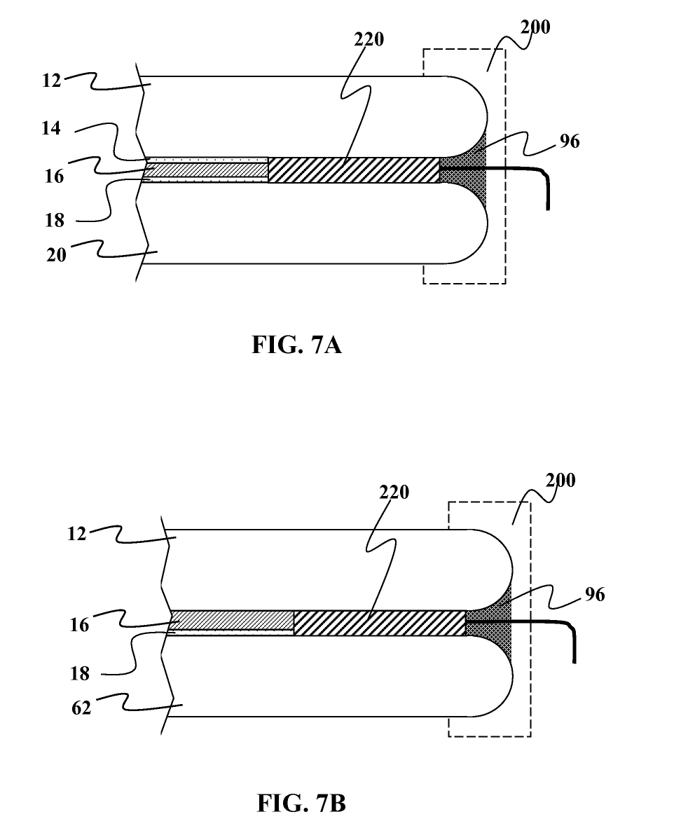

FIG. 7A shows an embodiment wherein edge tape 220 is included along the entire perimeter of the module to provide weatherproofing and moisture barrier qualities to the module. In one embodiment, the edge tape may be about 5 mm to about 20 mm in width (not thickness) around the edges of the module. In one embodiment, the tape may be butyl tape and may optionally be loaded with desiccant to provide enhanced moisture barrier qualities.

FIG. 7B shows a substantially similar embodiment to that in FIG. 7A except that the solar cell 16 is formed directly on one of the support layers. In FIG. 7B, the solar cell 16 is formed directly on the top transparent module layer 12. Optionally, the solar 16 maybe formed directly on the bottom layer

### Module Interconnection

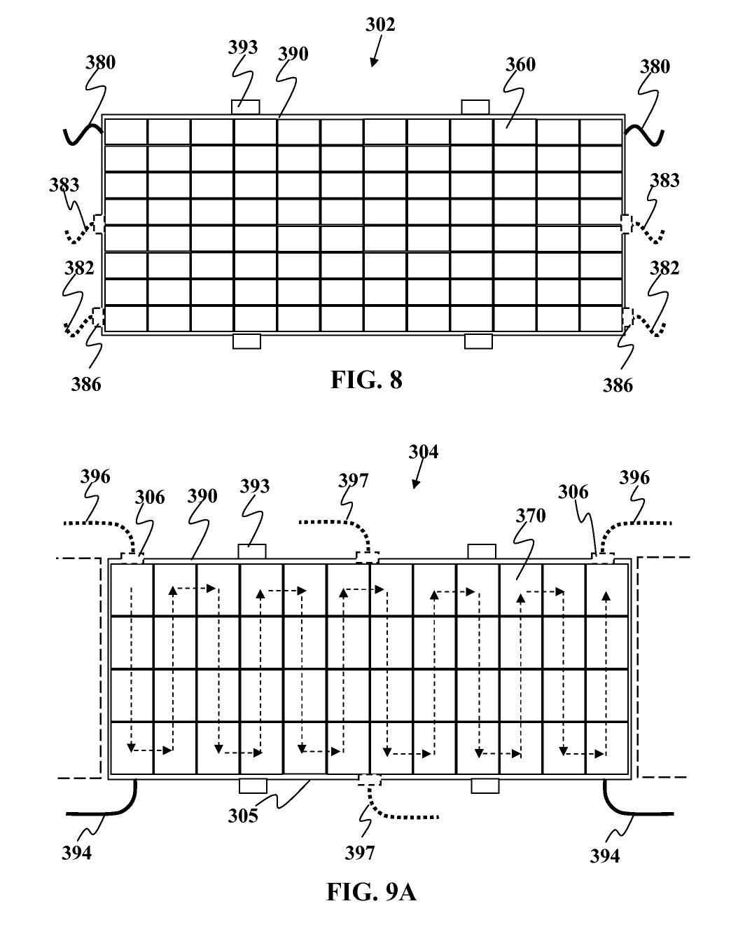

Referring now to FIG. 8, embodiments of the modules 302 used with the above assemblies will be described in further detail. FIG. 8 shows one embodiment of the module 302 with a plurality of solar cells 360 mounted therein. In one embodiment, the cells 360 are serially mounted inside the module packaging. In other embodiments, strings of cells 360 may be connected in series connections with other cells in that string, while string-to-string connections may be in parallel. FIG. 8 shows an embodiment of module 302 with 96 solar cells 360 mounted therein. The solar cells 360 may be of various sizes. In this present embodiment, the cells 360 are about 135.0 mm by about 81.8 mm. As for the module itself, the outer dimensions may range from about 1660 mm to about 1665.7 by about 700 mm to about 705.71 mm. Optionally, in other embodiments, the solar modules each have a weight less than about 35 kg (optionally about 31 kg or less) and a length between about 1900 mm and about 1970 mm, and a width between about 1000 mm and about 1070 mm.

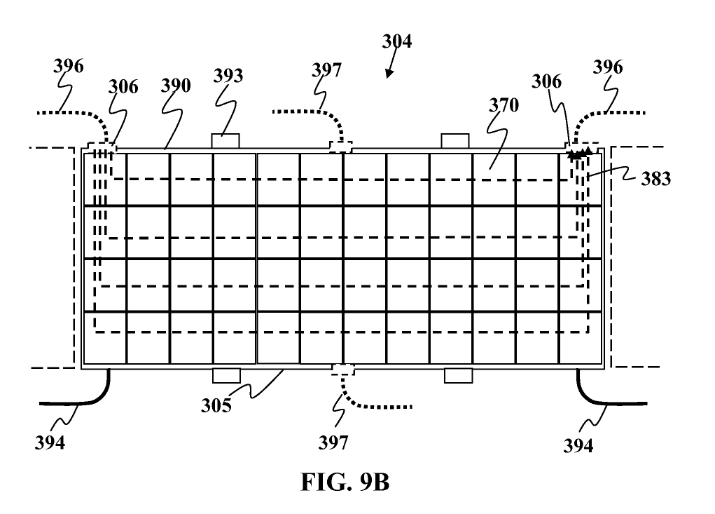

FIG. 9A shows yet another embodiment of module 304 wherein a plurality of solar cells 370 are mounted there. Again, the cells 370 may all be serially coupled inside the module packaging. Alternatively, strings of cells may be connected in series connections with other cells in that string, while string-to-string connections may be in parallel. FIG. 9A shows an embodiment of module 302 with 48 solar cells 370 mounted therein. The cells 370 in the module 304 are of larger dimensions. Having fewer cells of larger dimension may reduce the amount of space used in the module 302 that would otherwise be allocated for spacing between solar cells. The cells 370 in the present embodiment have dimensions of about 135 mm by about 164 mm. Again for the module itself, the outer dimensions may range from about 1660 mm to about 1666 mm by about 700 mm to about 706 mm. Optionally, in another embodiment of the module, the outer dimensions of the largest module layer may range from about 1900 mm to about 1970 by about 1000 mm to about 1070 mm. These dimensions are exemplary and nonlimiting.

Optionally, the modules may be configured so that they are limited to weighing no more than about 36 kg. Optionally, the modules may be configured so that they are limited to weighing no more than about 32 kg. Optionally, the modules may be configured so that they are limited to weighing no more than about 30 kg. Optionally, the modules may be configured so that they are limited to weighing no more than about 28 kg. In one embodiment, the module may be sized to provide at least about 170 watts of power at AM 1.5G. In one embodiment, the module may be sized to provide at least about 180 watts of power at AM 1.5G. In another embodiment, the module may be sized to provide at least about 200 watts of power at AM 1.5G. In another embodiment, the module may be sized to provide at least about 220 watts of power at AM 1.5G. In another embodiment, the module may be sized to provide at least about 240 watts of power at AM 1.5G.

The ability of the cells 360 and 370 to be sized to fit into the modules 302 or 304 is in part due to the ability to customize the sizes of the cells. In one embodiment, the cells in the present invention may be non-silicon based cells such as but not limited to thin-film solar cells that may be sized as desired while still providing a certain total output. For example, the module 302 of the present size may still provide at least 100 W of power at AM 1.5G exposure. Optionally, the module 302 may also provide at least 5 amp of current and at least 21 volts of voltage at AM1.5G exposure. Details of some suitable cells can be found in U.S. patent application Ser. No. 11/362,266 filed Feb. 23, 2006, and Ser. No. 11/207,157 filed Aug. 16, 2005, both of which are fully incorporated herein by reference for all purposes. In one embodiment, cells 370 weigh less than 14 grams and cells 360 weigh less than 7 grams. Total module weight may be less than about 16 kg. In another embodiment, the module weight may be less than about 18 kg. Further details of suitable modules may be found in commonly assigned, co-pending U.S. patent application Ser. No. 11/537,657 filed Oct. 1, 2006, fully incorporated herein by reference for all purposes. Industry standard mount clips 393 may also be included with each module to attach the module to support rails.

Although not limited to the following, the modules of FIGS. 8 and/or 9A/9B may also include other features besides the variations in cell size. For example, the modules may be configured for a landscape orientation and may have connectors 380 that extend from two separate exit locations, each of the locations located near the edge of each module. In one embodiment, that may charged as two opposing exit connectors on opposite corners or edges of the module in landscape mode, without the use of additional cabling as is common in traditional modules and systems. Optionally, each of the modules 302 may also include a border 390 around all of the cells to provide spacing for weatherproof striping and moisture barrier.

Referring still to FIGS. 8 and 9A/9B, it should be understood that removal of the central junction box, in addition to reducing cost, also changes module design to enable novel methods for electrical interconnection between modules. As seen in FIG. 8, instead of having all wires and electrical connectors extending out of a single central junction box that is typically located near the center of the module, wires and ribbons from the module 302 may now extend outward from along the edges of the module, closest to adjacent modules. The solar cells in module 302 are shown wherein first and last cells are electrically connected to cells in adjacent modules. Because the leads may exit the module close to the adjacent module without having to be routed to a central junction box, this substantially shortens the length of wire or ribbon need to connect one module to the other. The length of a connector 380 may be in the range of about 5 mm to about 500 mm, about 5 mm to about 250 mm, about 10 mm to about 200 mm or no more than 3× the distance between the closest edges of adjacent modules. Some embodiments have wire or ribbon lengths no more than about 2× the distance between the edges of adjacent modules. These short distance wires or ribbons may be characterized as microconnectors that may substantially decrease the cost of having many modules coupled together in close proximity, as would be the case at electrical utility installations designed for solar-based power generation.

By way of nonlimiting example, the connector 380 may comprise of copper, aluminum, copper alloys, aluminum alloys, tin, tin-silver, tin-lead, solder material, nickel, gold, silver, noble metals, or combinations thereof. These materials may also be present as coatings to provide improved electrical contact. Although not limited to the following, in one embodiment, a tool may use a soldering technique to join the electrical leads together at the installation site. Optionally, in other embodiments, techniques such as welding, spot welding, reflow soldering, ultrasonic welding, arc welding, cold welding, laser welding, induction welding, or combinations thereof may be used. Soldering may involve using solder paste and/or solder wire with built-in flux.

As seen in FIG. 8, some embodiments may locate the connectors 382 (shown in phantom) at a different location on the short dimension end of the module 302. Optionally, an edge housing 306 (shown in phantom) may also be used with either connectors 380 or 382 to secure the connectors to module 302 and to provide a more robust moisture barrier. Optionally, as seen in FIG. 8, some embodiments may have the connector 383 extending closer to the mid-line of the short dimension end of the module.

FIG. 9A shows one variation on where the connectors exit the module 304. The connectors 394 are shown to exit the module 304 along the side 305 of the module with the long dimension. However, the exits on this long dimension end are located close to ends of the module with the short dimensions, away from the centerpoint and/or centerline of the module. This location of the exit on the long dimension may allow for closer end-to-end horizontal spacing of modules with the ends of adjacent modules 395 and 396 (shown in phantom) while still allowing sufficient clearance for the connectors 394 without excessive bending or pinching of wire therein. As seen in FIG. 9A, other embodiments of the present invention may have connectors 396 (shown in phantom) which are located on the other long dimension side of the module 304. Optionally, some embodiments may have one connector on one long dimension and another connector on the other long dimension side of the module (i.e. kitty corner configuration). In still further embodiments, a connecter 397 may optionally be used on the long dimension of the module, closer to the midline of that side of the module. As seen in FIG. 9A, edge housings 306 (shown in phantom) may also be used with any of the connectors shown on module 304.

FIG. 9A also shows how the cells may be series interconnected as indicated by arrows 381. By way of example and not limitation, the edge housings may be coupled to the first cell and the last cell in the string, respectively. In one embodiment, an edge housing is placed in proximity to the first cell. Another edge housing is placed in proximity to the last of the series interconnected cells. This substantially reduces the “home run” of bus bars or wires to connect the last cell or the first cell to a central location where a central junction box is located. This results in a substantial materials savings over the course of a large number of modules.

Other embodiments, some cells may be connected in parallel electrical connection. In such embodiments, additional edge housings may be used to couple parallel strings. As seen in FIG. 9B, other embodiments may have more than one wire 383 exiting from the edge housing for different cell strings. These are still edge housings, but there may be more than one set of wires exiting therein.

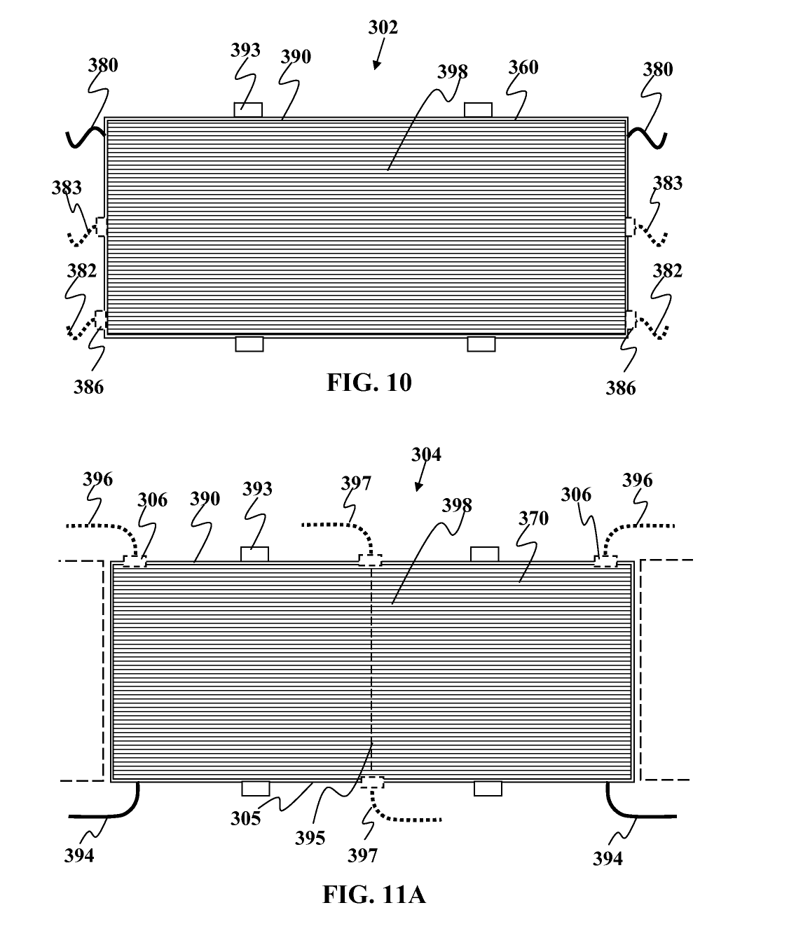

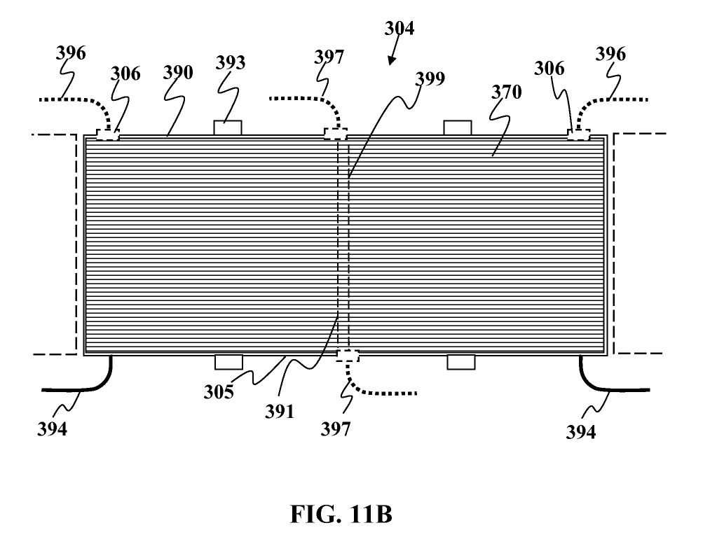

Referring now to FIGS. 10, 11A, and 11B, it is shown that the edge housings of FIGS. 8, 9A, and 9B may be adapted for use with solar cells 398 of other configurations. FIG. 10 shows that the solar cells 398 are of extremely long, elongate configuration. In one embodiment, each solar cell 398 may run the length of the module within the area surrounded by the edge tape moisture barriers. As seen in FIG. 11A, these elongate cells may be coupled to have electrical leads extending outward from any of the positions shown in the two figures. In one embodiment, both electrical leads are on the same side of module. In another embodiment, they are on different sides. In a still further embodiment, they are diagonal from each other. In yet another embodiment, they are on opposing sides. The elongate cells 398 may be strung together by one or more centerline connector(s) positioned along the midline 396.

FIG. 11B shows that there may be two bus bars 391 and 399. They may be coupled to every other cell or other configuration to allow for series or parallel interconnection between cells.

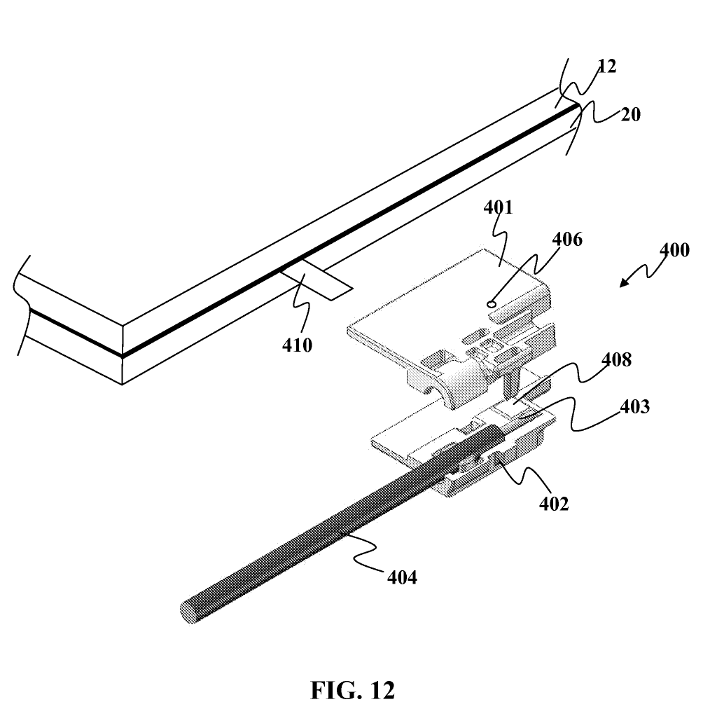

Referring now to FIG. 12, yet another embodiment of the present invention will now be described. FIG. 12 provides a more detailed description of an edge housing 400 that enables the electrical connection of one electrical conductor to another at the edge of a multilayer flat panel or module while providing electrical, environmental, and mechanical protection to both cables. The edge housing 400 wraps around the edge of the solar module at the location of the electrical lead exit and is bonded to the module layers at all points surrounding the conductor exit, providing an environmental seal, and mechanical support for the edge housing 400. In the present embodiment, the edge housing 400 includes an upper half 401 and a lower half 402. The edge housing 400 may optionally have a set screw or other means of providing mechanical pressure to electrically connect the two bare conductors within the module. The second conductor 403 is mechanically connected to the edge housing by means of a compression fitting or adhesive. The second conductor 403 may be a round wire with an insulating layer 404. Entry and exit holes 406 for the injection of a potting or encapsulating material exist in the module, providing an environmental seal to the conductor junction. The edge housing 400 may define a cavity 408 for receiving the electrical lead 410 and to provide room for encapsulating material.

Using the edge as an exit area for the electrical lead in a solar module provides several cost advantages due to not requiring any holes to be cut in the glass or potting material. However, in this method the edge sealant for the module is breached by the conductor which makes environmentally sealing the edge of the panel difficult. The present embodiment of the invention provides an insulated electrical joint and mechanical strain relief for the second cable leading away from the edge housing. This advantageously allows for the transition of a flat wire to round wire. In addition to providing a method for sealing and securing an edge exiting flat conductor, the present embodiment of the invention provides a housing that is easy to assembly in an automated many by providing locating and retaining features for the two conductors involved in the connection.

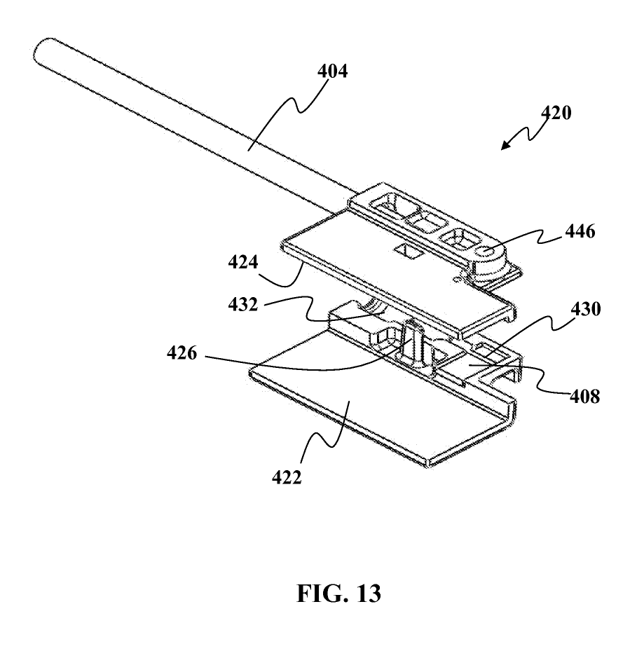

Referring now to the embodiment of FIG. 13, several features of the edge housing 420 will be described in more detail. Two large sealing and bonding surfaces 422 and 424 allow the edge housing 420 to be bonded to the planar portions of the module. Retention features for the two edge housings are also included. This may involve tabs 426 to hold the two halves together. Optionally, a snap feature is provided to hold the two halves of the edge housing 420 together. A cavity 430 is provided within the edge housing 420 to receive the round wire 403. The cavity 432 may be shaped to mechanically compress or pinch certain areas along the wire insulation 404 for retention purposes. A feature is provided in the edge housing to provide mechanical pressure on the joint between the two electrical contacts, ensuring an electrical connection. This may be accomplished in terms of sizing the cavity 408 and 430 to provide the desired mechanical compression when the halves of the edge housing are brought together. Additionally, the connecter 420 defines therein a channel connecting all open space within the module so as to be potted with a moisture barrier compound. In one embodiment, this allows an edge housing to be formed without air therein once potting material is injected into the channel.

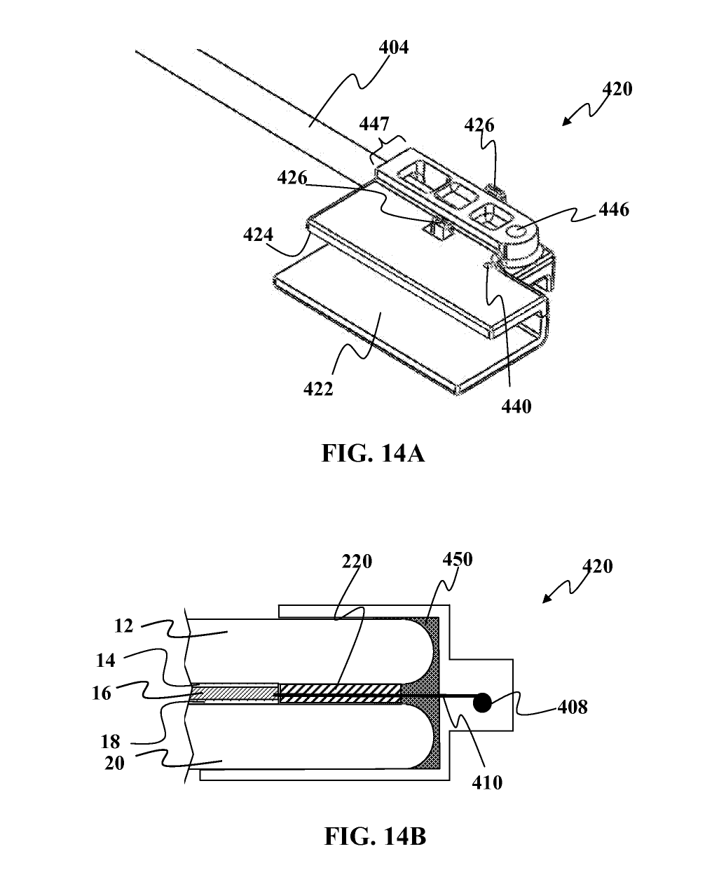

FIG. 14A shows the embodiment of FIG. 13 when the two halves of the housing of edge housing 420 are brought together. The halves may brought together first and then positioned to engage the module. Optionally, one half may first be adhered to the module and positioned so that the electrical lead is in the cavity 408. Then the second half of the edge housing 420 is then engaged to complete the edge housing and attach it to the module. In one embodiment, the two halves of edge housing 420 comprises of two injection molded parts which can be connected by a mechanical snap mechanism, and locate relative to one another via a locating feature. The body contains a hole 440 in which to inject potting material to fill any air space around the flat electrical conductor exiting the solar panel. The body is also breached by a threaded hole 446 into which a screw can be inserted so as to apply mechanical pressure to the joint between the two conductors. The body will also contain a feature allowing strain relief to the exiting cable. It should be understood that the upper portion 447 may be reduced in height to be flush with the upper piece that provides support surface 424.

As seen in FIG. 14B, this edge housing 420 will prevent water vapor from entering a breach in the edge of a multilayer solar panel, allowing the edge to be used as an electrical conductor exit. The open spaces in the edge housing 420 are filled with potting material 450 to form a moisture barrier therein. The potting material 450 may be injected into the edge housing 420 through opening 440 after the edge housing 420 is mounted onto the module or optionally before mounting. The edge housing 420 may be configured so that the potting material will have increased surface area contact with the module and present a long pathway for any moisture trying to enter into the module. The edge housing 420 may be designed to prevent damage to the cells by moisture ingress, provide mechanical strain relief to the exiting cable, and enable fast, easy manufacture of the solar panel.

Although not limited to the following, the potting material 450 may be comprised of one or more of the following: Tru-Seal®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof.

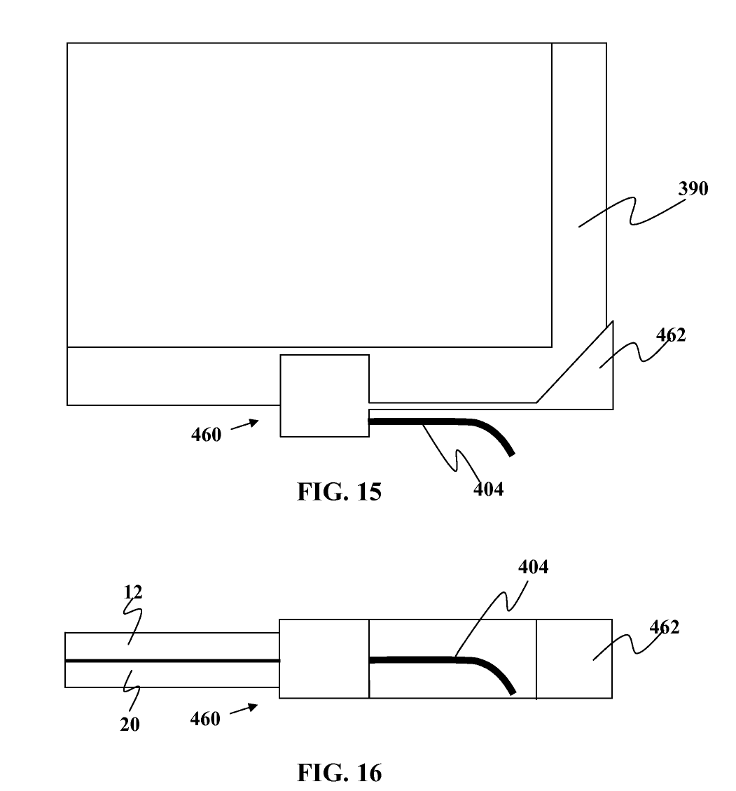

Referring now to FIG. 15, another embodiment of an edge housing 460 will now be described. This embodiment shows that the edge housing 460 may extend to cover a corner of the module. A corner portion 462 of the module allows for greater structural support for lateral forces that may be encountered by the edge housing 460. As seen in FIG. 15, the edge housing 460 may be designed to overlap only non-photovoltaic portions of the module, which in this case is the edge tape moisture barrier 390. FIG. 16 shows a side view of the edge housing 460. In this embodiment, the height that the edge housing 460 extends above the module layer 12 or module layer 20 is no more than about 0.5 cm (above or below the respective module layer). In some embodiments, the edge housing does not extend more than 0.25 cm above or below the respective module layer. In some embodiments, the edge housing does not extend more than 0.10 cm above or below the respective module layer. It should be understood that the some embodiments of the edge housing may have no portion that covers any top surface of the module. Other embodiments may have edge housings that only cover the top surface of the module.

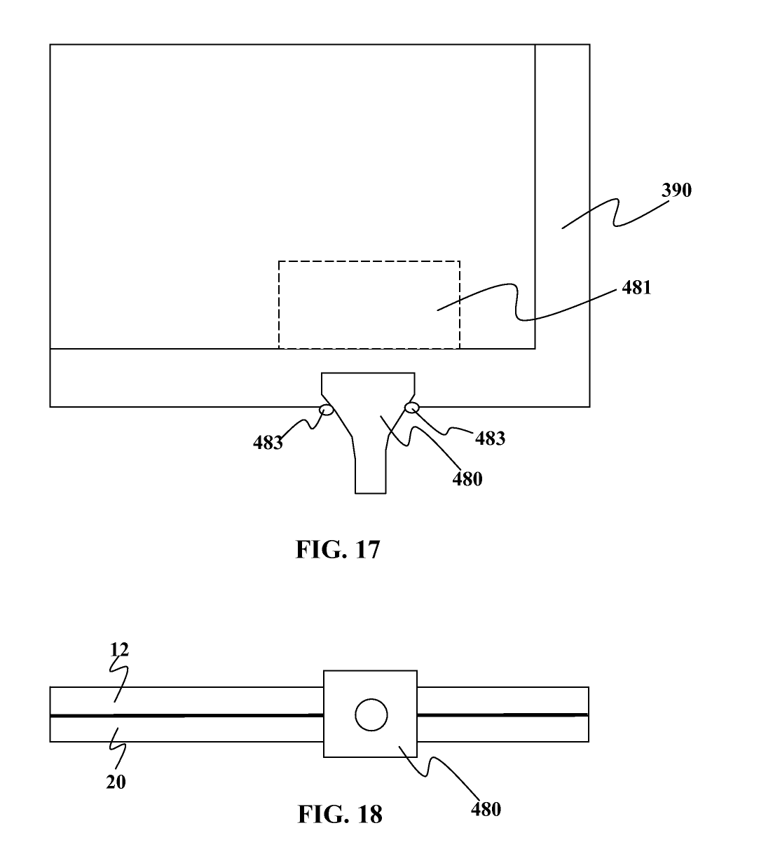

Referring now to FIGS. 17 and 18, a still further embodiment of an edge housing 480 will now be described. The edge housing 480 may be configured as a sleeve or boot that will slide over the electrical lead extending outward from the module. The sleeve shaped edge housing 480 may be a single integrated piece or it may be two halves that are joined together. FIG. 17 shows that in some embodiments, extra amounts of moisture barrier tape 481 may be provided to increase the area near the electrical lead exit. This extra area barrier 481 may optionally be included for any of the embodiments herein and may oval, curved, square, triangular or other shaped. It should also be understood that additional moisture barrier material may be applied to the exterior of the edge housing 480 at the junctions 483. This additional barrier material may also be adapted for use with all other embodiments herein. The additional barrier on the exterior of the edge housing may be applied partially or completely over the edge housing.

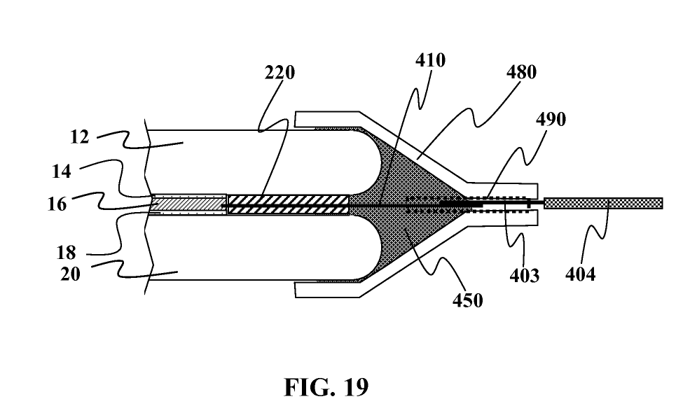

FIG. 19 shows a cross-sectional view of edge housing 480, wherein the interior of the edge housing 480 is filled with a potting material 450. This helps to form a waterproof moisture barrier that minimizes the possibility of water damage to the module. Optionally, the edge housing 480 may have a solder sleeve 490 such as that available from Tyco Electronics wherein the sleeve 490 will contain solder and heat shrink material that will both mechanically secure the electrical lead 410 and provide electrical connection of the two wires therein. In other embodiments, other methods of mechanical coupling may be used to secure the electrical elements together.

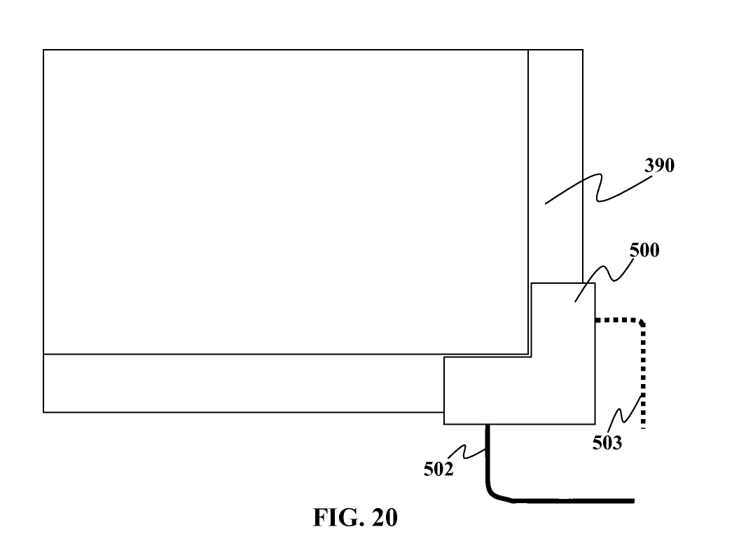

FIG. 20 shows a still further embodiment of a corner edge housing 500 wherein the edge housing has an L-shaped configuration to be positioned at the corner of the module. The electrical lead 502 (or optionally electrical lead 503) may exit from the edge housing 500 at either the short dimension side or the long dimension side as appropriate.

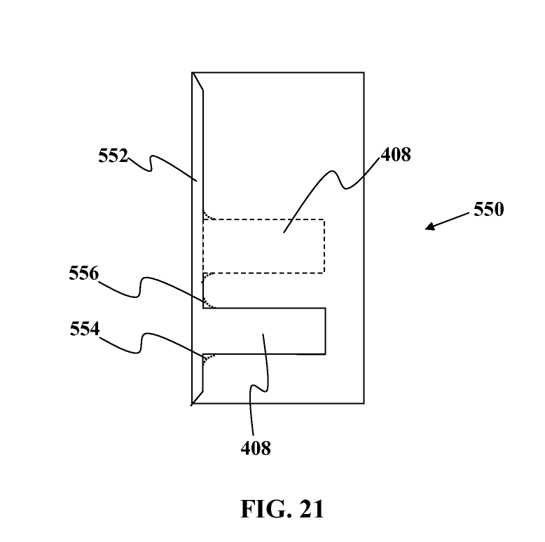

FIG. 21 shows a simplified cross-sectional view of an edge housing 550 wherein the cavity 408 is used to receive the electrical lead from the module. A cavity 552 may be used to provide an elongate area for the potting material to engage surfaces of the module. As seen, in some embodiments, the cavity 408 may be positioned in a more central location (shown in phantom) if more moisture protection may be obtained around the electrical lead exit in that configuration. Also, as seen in FIG. 21, the edges of the cavity 408 may be rounded as indicated by phantom lines 554 and 556 to provide more surface area contact and a smoother transition between differently shaped portion of the cavity. It should be understood that the rounded edges and the cavity 552 may be adapted for use with any of the embodiments herein.

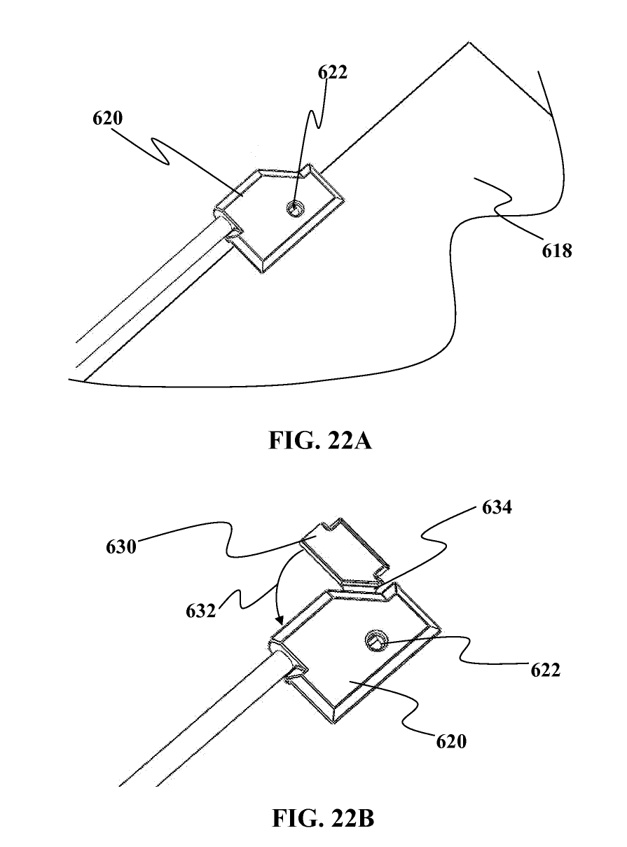

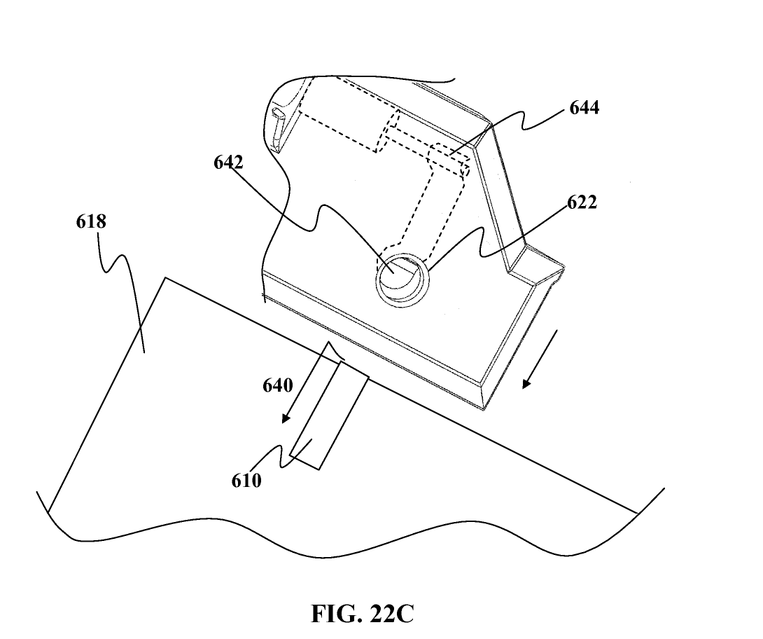

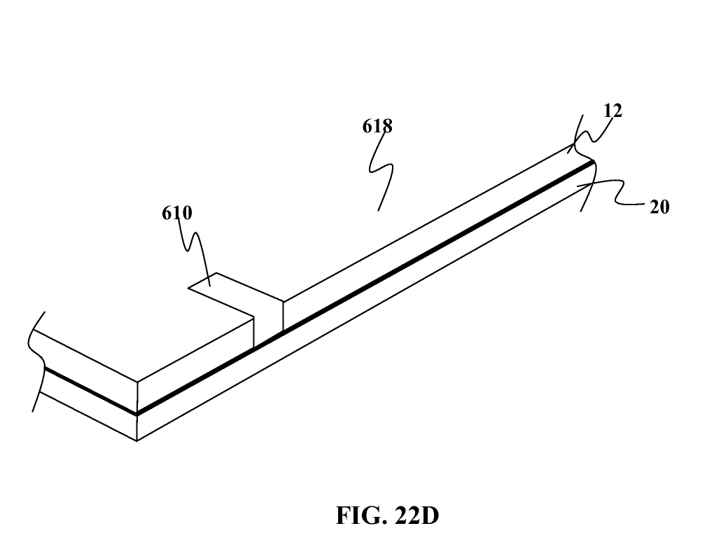

Referring now to FIG. 22A, yet another embodiment of the edge housing 620 will be described. This edge housing is coupled to the edge of the module and may be single piece device as more clearly seen in FIG. 22B. An opening 622 may be provided on the edge housing 620 to allow for infusion of pottant or adhesive into the edge housing. The opening 622 may also allow for soldering or welding of electrical leads that are housed inside the edge housing 620.

FIG. 22B shows how the edge housing 620 can be formed as a single piece unit with a flap portion 630 that can be folded over to clamp against an opposing surface of the edge housing 620. Arrow 632 shows how the opposing portion 630 may be folded about the hinge 634 to clamp against the other surface of the edge housing 620 in a clam-shell fashion.

FIG. 22C show a close-up view of edge housing 620. The edge housing 620 may slide over the module 618 and overlap the electrical lead 610. In this embodiment, the electrical 610 may extend out the edge and is then wrapped over a planar surface of the module 618. This folded configuration is indicated by arrow 640. The electrical lead may then be in contact with metal tab 642 inside the edge housing 620. In the present embodiment, the tab 622 (partially shown in phantom) extends inside the edge housing 620 to coupled to a wire leading outside the edge housing to connect to another module. The tab 622 maybe curved at a opposite end 644 to connect with the wire. The opening 622 allows the metal tab 642 to be soldered, welded, or otherwise electrically coupled t the electrical lead 610 coming from the module. The connection between the electrical lead 610 and the tab 642 may be made before or after the edge housing is placed on the module. It should be understood than the edge housing 620 may also be adapted for use with glass-glass type modules as set forth in U.S. Patent Application Ser. No. 60/862,979 filed Oct. 25, 2006.

FIG. 22D shows that for this present embodiment, the electrical lead 610 extends outward from between the module layers and is then contoured along a side surface of the module until it reach a back side surface of module 618. Optionally, the electrical lead 610 may extend outward to reach a front side surface of module 618. The end of the electrical lead 610 may be flat against the surface of module 618 or it may be otherwise configured

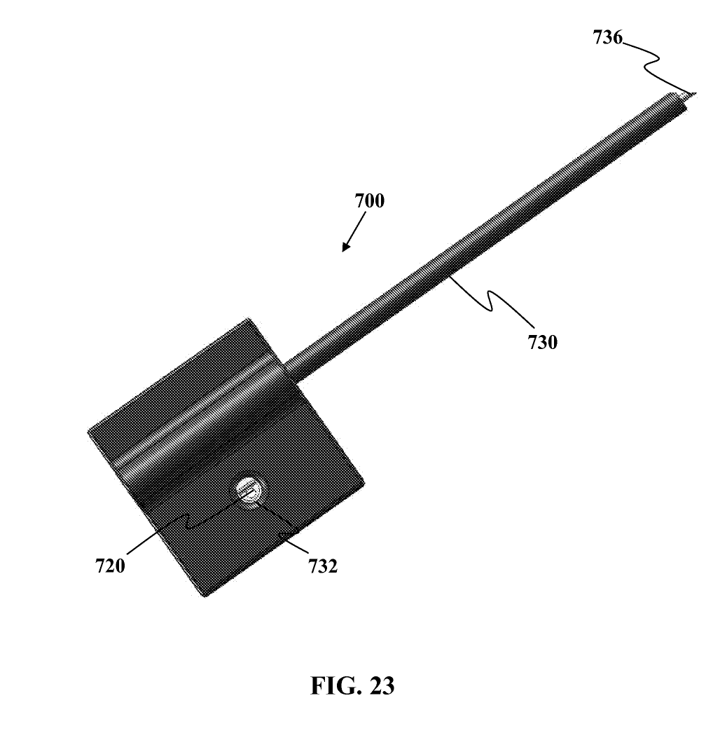

Referring to FIG. 23, this embodiment of the edge housing 700 is shown wherein the wire 730 is coupled closer to the mid-line of the edge housing. Ribs may be on the underside of the edge housing 700 or on other surfaces of the housing. This may be for rigidity and to allow pottant to flow therein. FIG. 23 shows that the core 736 of the wire 730 is more easily visualized in this figure. As seen in FIG. 23, the core 736 may extend to an interior area of the edge housing 700 where it will be coupled to the metal connector 720. Although not limited to the following, the interior of the edge housing 700 may be molded to hold the metal connector 720 in place. This underside view also shows the opening 732 through which the metal connector 720 is visible. Pottant material, sealing material, or the like may be injected through the opening. Wires and/or connectors can also be soldered or otherwise joined through the opening 732. It should also be understood that the edge housing 700 or any of the housings herein may be one integral piece or it may be multiple pieces joined together. In one example, the internal metal pieces are coupled to the module and then that outer shell which may be metal or polymer is placed over the metal internal parts.

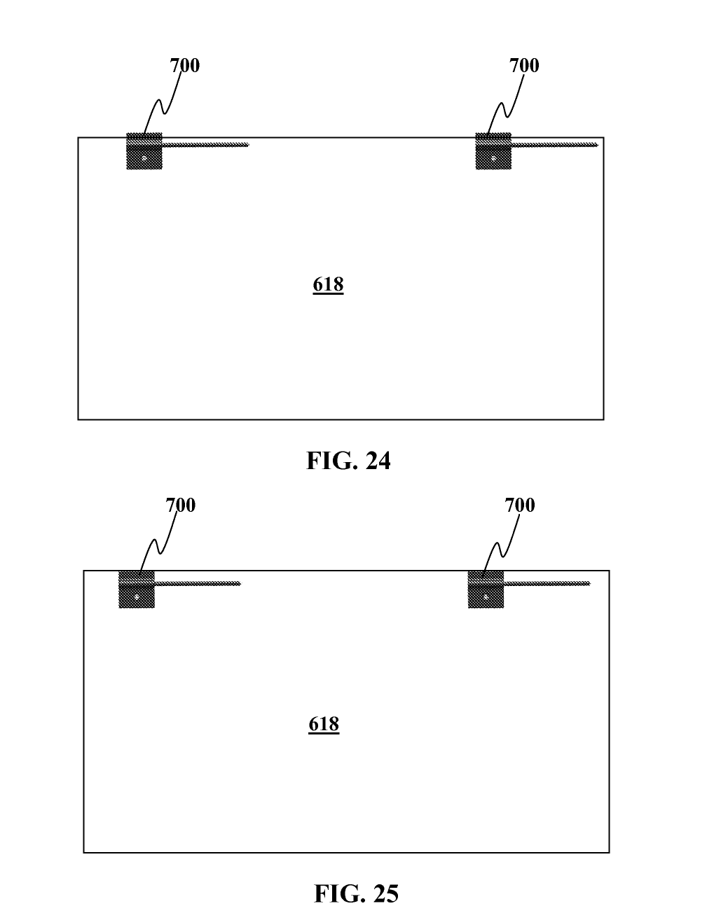

FIG. 24 shows that in one embodiment, the edge housing 700 may be positioned to extend beyond the perimeter of the module layer. It may wrap up along the side surface of the module 618.

FIG. 25 shows that in another embodiment, the edge housing 700 may be positioned to remain entirely within the perimeter of the module layer and not extend along the side edge surface of the module 618.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, although glass is the layer most often described as the top layer for the module, it should be understood that other material may be used and some multi-laminate materials may be used in place of or in combination with the glass. Some embodiments may use flexible top layers or coversheets. By way of nonlimiting example, the backsheet is not limited to rigid modules and may be adapted for use with flexible solar modules and flexible photovoltaic building materials. Embodiments of the present invention may be adapted for use with superstrate or substrate designs. It may be used with modules that have flat solar cells, elongate solar cells, tubular solar cells, conical solar cells, or cells of other shapes. Details of modules with thermally conductive backplanes and heat sinks can be found in commonly assigned, co-pending U.S. patent application Ser. No. 11/465,783 (Attorney Docket NSL-089) filed Aug. 18, 2006 and fully incorporated herein by reference for all purposes. Other backsheet materials may also be used and is not limited to glass only embodiments. The housing of the edge housing could be made of any material by any method. The edge housing could be designed for hand assembly instead of automated assembly, leaving out locating features. The edge housing could be designed without the channel and holes to allow potting. The edge housing could be designed to allow two or more edge housings to exit the solar module, and could include diode linked between the exiting conductors. Some embodiments may have lower surfaces 422 greater in area than the surface 424. Optionally, some embodiments may have surfaces 424 greater than surfaces 422. In one embodiment, both electrical leads or edge housings are on the same side of module. In another embodiment, they are on different sides. In a still further embodiment, they are diagonal from each other. In yet another embodiment, they are on opposing sides. The shape of the edge housing may be those as shown herein or may oval, curved, square, triangular, hexagonal, circular, polygonal, combinations thereof, or other shaped (as viewed from above or from the side). Additionally, at least some of the embodiments herein only have one wire exiting from the edge housing. Some embodiments of edge housing may have one or more openings 732 to allow for connection of electrical connections in the housing and/or to allow ease of filling of encapsulant or pottant therein. Some embodiments have at least two openings 732 which may be on the same or different surfaces of the edge housing.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. patent application Ser. No. 11/465,787 filed Aug. 18, 2006 and PCT patent application PCT/US07/76259 Aug. 18, 2007 are both fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A photovoltaic module comprising:
a plurality of photovoltaic cells positioned between a transparent module layer and a backside module layer;
a first edge-exiting electrical lead extending outward from an edge of the module; and
a second edge-exiting electrical lead extending outward from an edge of the module.

2. The module of claim 1 wherein the first edge-exiting electrical lead extends outward from the module from between the transparent module layer and the backside module layer, wherein the first edge-exiting electrical lead is couplable to an adjacent module without passing the lead through a central junction box; and
a second edge-exiting electrical lead extending outward from the module from between the transparent module layer and the backside module layer, wherein the second edge-exiting electrical lead is couplable to another adjacent module without passing the lead through a central junction box.

3. The module of claim 1 wherein the edge exiting leads are each housed within an edge mounted edge housing that contains only one connection directly connected to at least one cell in the module.

4. The module of claim 1 wherein the edge exiting leads are each housed within an edge mounted edge housing that contains only one connection directly connected to only one cell in the module.

5. The module of claim 1 wherein the edge exiting leads are each housed within an edge mounted edge housing that connects to a wire exiting through an opening in the backside module layer.

6. The module of claim 1 wherein the module is a frameless module.

7. The module of claim 2 wherein the backside module layer, transparent module layer, and the cells therebetween are coupled together without a frame extending around a perimeter of the module layers.

8. The module of claim 1 comprises a glass-glass module.

9. The module of claim 1 further comprising:
a first edge housing for securing the first electrical lead to the module and providing a moisture barrier at a first electrical lead exit from the module;
a second edge housing for securing the second electrical lead to the module and providing a moisture barrier at a second electrical lead exit from the module.

10. The module of claim 9 wherein the first edge housing and the second edge housing each define an interior space configured to accommodate encapsulant material injected into the space to form the moisture barrier.

11. The module of claim 9 wherein the first edge housing and the second edge housing each have an opening allowing encapsulant material to be injected into the connecter to form a moisture barrier after the connecter is mounted onto the module.

12. The module of claim 9 wherein the first edge housing and the second edge housing each have a surface that engages the transparent module layer and a second surface that engages the backside module layer.

13. The module of claim 9 wherein the first edge housing and the second edge housing engages only one of the following: the transparent module layer or the backside module layer.

14. The module of claim 9 wherein the first edge housing and the second edge housing are each sized to receive a flat wire entering the edge housing and couple the flat wire to a round wiring exiting the edge housing.

15. The module of claim 9 wherein the first edge housing and the second edge housing are each sized to receive a flat aluminum-based wire entering the edge housing and couple the flat aluminum-based wire to a round copper-based wire exiting the edge housing.

16. The module of claim 9 wherein the first edge housing and the second edge housing are spaced apart from one another, with the first edge housing closer to one end of the module and the second edge housing to an opposite end of the module.

17. The module of claim 9 wherein the first edge housing and the second edge housing are each positioned on the module to cover a corner of the module.

18. The module of claim 9 wherein the first edge housing and the second edge housing extend no more than about 1 cm above the transparent module layer.

19. The module of claim 9 wherein the first edge housing and the second edge housing extend no more than about 0.5 cm below the backside module layer.

20. The module of claim 9 wherein the first edge housing and the second edge housing are mounting in a manner along the edges of the module to allow for substantially flush stacking of modules against one another.

21-24. (canceled)

25. The module of claim 1 further comprising a pottant layer between the photovoltaic cells and either the transparent module layer or the backside layer, wherein the pottant layer comprises of one or more of the following: ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, or combinations thereof.

26-30. (canceled)

31. The module of claim 1 wherein the first electrical lead or the second electrical lead has a length no more than about 30 cm.

32. The module of claim 1 wherein the module is in landscape configuration defined by a long dimension and a short dimension, wherein the first electrical lead extends from the module along the short dimension.

33. The module of claim 1 wherein the module is in landscape configuration defined by a long dimension and a short dimension, wherein the first electrical lead extends from the module along the long dimension, closer to one end of the module than a middle of the module.

34. The module of claim 1 wherein the first electrical lead extends outward from one edge of the module and the second electrical lead extend outward from the same edge of the module.

35. The module of claim 1 wherein the first electrical lead extends outward from along one edge of the module and the second electrical lead extends outward from a different edge of the module.

36. The module of claim 1 wherein a first cell in the module comprises a dummy cell of non-photovoltaic material to facilitate electrical connection to other solar cells in the module.

37. The module of claim 1 wherein a flat, inline bypass diode takes the place of one of the cells in the module.

38-43. (canceled)

44. An edge housing for use with a solar module, the edge housing comprising:
a housing defining an opening for receiving an electrical lead from the module; and
a module interface surface on the housing configured to mount the housing along an edge of the module;
wherein the housing defines a cavity for receiving encapsulant to create a waterproof seal with the module and the electrical lead.

45. The edge housing of claim 44 wherein the housing comprises of an upper part and a lower part separable from one another.

46-68. (canceled)

69. A method comprising:
providing a plurality of frameless, rigid photovoltaic modules;
mounting a plurality of edge housings over electrical leads extending outward from the edges of the modules, wherein all electrical leads on one module exits the module without passing through the same edge housing and without passing through a central junction box.

70-81. (canceled)

82. A photovoltaic module comprising:
a plurality of photovoltaic cells positioned between a transparent module layer and a backside module layer;
a first electrical lead extending outward from the module; and
a second electrical lead extending outward from the module,
a first edge housing the first electrical lead;
a second edge housing the second electrical lead, wherein the second edge housing is spaced apart from the first edge housing;
wherein at least one of the leads exits through an opening in the backside module layer to enter the edge housing.
